(19) United States
(12) Patent Application Publication
(10) Pub. No.: US 2024/0060185 A1
(43) Pub. Date: Feb. 22, 2024

(54) SUBSTRATE PROCESSING APPARATUS

(71) Applicant: SAMSUNG ELECTRONICS CO., LTD., suwon-si (KR)

(72) Inventors: Yeontae KIM, suwon-si (KR); Yihwan KIM, Suwon-si (KR); Hunyong PARK, Suwon-si (KR); Keesoo PARK, Suwon-si (KR); Janghwi LEE, Suwon-si (KR); Sungho JANG, Suwon-si (KR)

(21) Appl. No.: 18/231,400

(22) Filed: Aug. 8, 2023

(30) Foreign Application Priority Data
Aug. 19, 2022 (KR) 10-2022-0104309
Aug. 26, 2022 (KR) 10-2022-0107906

(51) Int. Cl. C23C 16/48; C23C 16/458

(52) U.S. Cl. CPC C23C 16/482; C23C 16/4585

(57) ABSTRACT

A substrate processing apparatus includes a chamber including a susceptor to support a substrate, a reflective housing outside the chamber, a light source in the reflective housing, the light source being configured to emit a light toward the susceptor, and a light adjuster between the light source and the susceptor, the light adjuster including a support portion supported inside the chamber and a lens coupled to the support portion, and the lens including a transmission portion configured to transmit the light and a scattering pattern portion configured to scatter the light.

### CROSS-REFERENCE TO RELATED APPLICATIONS

This application is based on and claims priority under 35 U.S.C. § 119 to Korean Patent Application No. 10-2022-0104309, filed on Aug. 19, 2022, and Korean Patent Application No. 10-2022-0107906, filed on Aug. 26, 2022, in the Korean Intellectual Property Office, the disclosures of which are incorporated by reference herein in their entireties.

### BACKGROUND

### 1. Field

Embodiments relate to a substrate processing apparatus, and particularly, to a substrate processing apparatus for forming a thin film on a substrate.

### 2. Description of the Related Art

In general, a semiconductor device may be manufactured through a plurality of unit processes. The unit processes may include, e.g., a thin film deposition process, a diffusion process, a heat treatment process, a photolithography process, a polishing process, an etching process, an ion implantation process, and a cleaning process. Among the unit processes, the thin film deposition process may include a process of forming a thin film on a substrate. The thin film may be formed of single crystal, polycrystalline, or amorphous silicon. A single crystal thin film may have a lower lattice defect density than a polycrystalline thin film and an amorphous thin film.

### SUMMARY

According to embodiments, there is provided a substrate processing apparatus including a chamber that includes a susceptor configured to support a substrate, a reflective housing provided outside the chamber, a light source provided in the reflective housing and configured to emit light to the substrate, and a light adjuster provided between the light source and the substrate, and including a support portion supported inside the chamber and a lens coupled to the support portion, wherein the lens includes a transmission portion configured to transmit the light therethrough, and a scattering pattern portion configured to scatter the light.

According to embodiments, there is provided a substrate processing apparatus including a chamber that includes a susceptor configured to support a substrate, a reflective housing provided outside the chamber, a light source provided in the reflective housing and configured to emit light to the substrate, and a light adjuster provided between the light source and the substrate, and including a support portion supported inside the chamber and a lens coupled to the support portion, wherein the lens includes a transmission portion that is formed on a surface of the lens and configured to transmit the light therethrough, and a scattering pattern portion configured to scatter the light, and the scattering pattern portion includes a first pattern having a ring shape and a first inner radius, a second pattern having a ring shape and a second inner radius, and a third pattern having a ring shape and a third inner radius.

According to embodiments, there is provided a substrate processing apparatus including a chamber including a susceptor configured to support a substrate, a reflective housing provided outside the chamber, a light source provided in the reflective housing and configured to emit light having a wavelength in a range of about 100 nm to about 400 nm to the substrate, and a light adjuster provided between the light source and the substrate, and including a support portion supported inside the chamber and a lens coupled to the support portion, wherein the lens includes a transmission portion that is formed on a surface and configured to transmit the light therethrough, and a scattering pattern portion configured to scatter the light, the lens is aligned in a direction perpendicular to a center of the substrate and has a dome shape protruding in a direction opposite to a direction toward the substrate, the scattering pattern portion has, on the surface of the lens, a first pattern having a ring shape and a first inner radius, a second pattern having a ring shape and a second inner radius greater than the first inner radius, and a third pattern having a ring shape and a third inner radius greater than the second inner radius, the second pattern is outside the first pattern on the surface of the lens, and the third pattern is outside the second pattern on the surface of the lens, an arithmetic mean roughness of the first pattern is greater than an arithmetic mean roughness of the second pattern, the arithmetic mean roughness of the second pattern is greater than an arithmetic mean roughness of the third pattern, and the arithmetic mean roughness of the first pattern, the arithmetic mean roughness of the second pattern, and the arithmetic mean roughness of the third pattern are about 0.5 to about 2.

### BRIEF DESCRIPTION OF THE DRAWINGS

Features will become apparent to those of skill in the art by describing in detail exemplary embodiments with reference to the attached drawings, in which:

FIG. 1 is a cross-sectional view illustrating a substrate processing apparatus according to an embodiment;

FIGS. 2 and 3 are cross-sectional views schematically illustrating states in which a light source of FIG. 1 emits light onto a substrate;

FIG. 4 is a perspective view of an embodiment of the light adjuster illustrated in FIG. 1.

FIG. 5 is a perspective view of a support portion illustrated in FIG. 4;

FIG. 6 is a plan view of the light adjuster illustrated in FIG. 4;

FIG. 7 is a perspective view of a light adjuster according to another embodiment;

FIG. 8 is a plan view of the light adjuster illustrated in FIG. 7;

FIG. 9 is a perspective view of the light adjuster according to another embodiment.

FIG. 10 is a plan view of the light adjuster illustrated in FIG. 9;

FIG. 11 is a graph of experimental data illustrating a thin film distribution when the light adjuster illustrated in FIG. 9 is used;

FIG. 12 is experimental data illustrating an intensity of light depending on regions of a substrate when the light adjuster illustrated in FIG. 9 is used;

FIG. 13 is experimental data illustrating a temperature distribution depending on regions of a substrate when a light adjuster is not used; and

FIG. 14 is experimental data illustrating a temperature distribution depending on regions of a substrate when the light adjuster illustrated in FIG. 9 is used.

### DETAILED DESCRIPTION

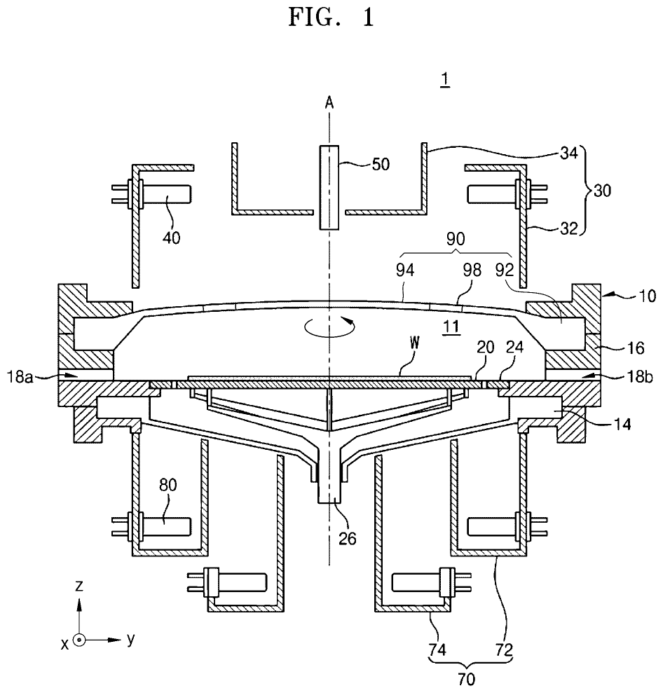

FIG. 1 is a cross-sectional view illustrating a substrate processing apparatus according to an embodiment.

Referring to FIG. 1, a substrate processing apparatus 1 may include a chamber 10, a susceptor 20, a reflective housing 30, a light source 40, a temperature measurer 50, and a light adjuster 90. The substrate processing apparatus 1 may further include a lamp-type epitaxy deposition apparatus.

The susceptor 20 supporting a substrate W may be provided in the chamber 10. The susceptor 20 may be configured to support and rotate the substrate W on an upper surface of the susceptor 20. The susceptor 20 may have a sufficiently wide surface to support all portions of one surface of the substrate W.

The reflective housing 30 may be provided at an outer upper portion of the chamber 10, e.g., the reflective housing 30 may be outside and above the chamber 10. The light source 40 may be provided in the reflective housing 30. A plurality of light sources 40 may be arranged in a circumferential direction of the reflective housing 30.

The chamber 10 may include the light adjuster 90, a lower chamber 14, and an edge ring 16. The light adjuster 90 is positioned between the light source 40 and the susceptor 20, e.g., between the light source 40 and the substrate W, and is made of a transparent material to cause the light emitted from the light source 40 to transmit therethrough toward the substrate W.

For example, the substrate processing apparatus 1 may further include a lower reflective housing 70 and a lower light source 80. A structure of the substrate processing apparatus 1 will be described below in detail.

The chamber 10 provides an internal space 11 for performing a thin film deposition process on the substrate W. In detail, the internal space 11 may be formed between the light adjuster 90 and the susceptor 20 inside the chamber 10. The internal space 11 may be maintained in a vacuum state. A vent hole connected to a vacuum pump may be formed in the internal space 11. The vacuum pump may maintain the internal space 11 in a vacuum state by sucking air before the thin film deposition process is performed. The vacuum state referred to herein indicates a state in which pressure of the internal space 11 is 1 Torr or less. That is, the vacuum pump may remove, e.g., suck, air until the pressure of the internal space 11 reaches 1 Torr or less.

According to an embodiment, the chamber 10 may include the light adjuster 90, the lower chamber 14, and the edge ring 16. The light adjuster 90, the lower chamber 14, and the edge ring 16 may be coupled to each other to form the internal space 11 therebetween.

The lower chamber 14 may have a dome shape or a funnel shape. According to an embodiment, the lower chamber 14 may be made of a transparent material. For example, the lower chamber 14 may include quartz or glass.

The edge ring 16 may surround edges of the light adjuster 90 and the lower chamber 14 and may couple the light adjuster 90 to the lower chamber 14, e.g., the edge ring 16 may continuously surround an entire perimeter of the light adjuster 90. According to an embodiment, the light adjuster 90 may be mechanically coupled to the edge ring 16 through an upper clamp ring. When the substrate W is loaded into or unloaded from the internal space 11, at least one of the light adjuster 90 and the lower chamber 14 may be separated from the edge ring 16. According to an embodiment, the substrate W may be loaded/unloaded through a slit door provided in the edge ring 16.

The edge ring 16 may have a gas inlet 18a and a gas outlet 18b. According to an embodiment, the edge ring 16 may have grooves connecting the inside of the chamber 10 to the outside thereof, and the respective grooves may be provided in the gas inlet 18a and the gas outlet 18b. The gas inlet 18a may be formed on one side of the edge ring 16, and the gas outlet 18b may be formed on the other side of the edge ring 16. The gas inlet 18a and the gas outlet 18b may be provided at positions opposite to each other, e.g., the gas inlet 18a and the gas outlet 18b may be on opposite sides of the edge ring 16. A process gas may be provided into the chamber 10 through the gas inlet 18a. When a process is completed, process gases and process by-products may be discharged to the outside of the chamber 10 through the gas outlet 18b. The process gas may include, e.g., silane (SiH₄), disilane (Si₂H₆), DCS (SiH₂C₁₂), or TCS (SiHCl₃)—.

The susceptor 20 may support and rotate the substrate W on an upper surface of the susceptor 20. The susceptor 20 may have a sufficiently large planar area to support all portions of one surface of the substrate W. The susceptor 20 may be made of a graphite material coated with a silicon material, e.g., silicon carbide (SiC), or a ceramic material, or other process resistant material.

According to one embodiment, a preheat ring 24 may surround, e.g., entire perimeter of, the susceptor 20. The preheat ring 24 may preheat the process gas to a preset temperature. Due to this, the process gas may be pyrolyzed into a gas form for single crystal growth. The support part 26 may support the susceptor 20. The support part 26 may elevate the susceptor 20 and rotate the susceptor 20 about a central axis A of the substrate W. For example, the susceptor 20 may rotate the substrate W at about 10 rpm to about 100 rpm. When the susceptor 20 rotates, the entire region of the substrate W may be uniformly processed.

According to an embodiment, the reflective housing 30 may be on an outer upper portion of the chamber 10, e.g., the chamber 10 may be between the reflective housing 30 and the lower chamber 14. The reflective housing 30 may cover the light adjuster 90, e.g., the reflective housing 30 may overlap an entire top surface of the light adjuster 90. The reflective housing 30 may include a first sub-reflective housing 32 and a second sub-reflective housing 34. The first sub-reflective housing 32 may be coupled to the second sub-reflective housing 34, e.g., the first sub-reflective housing 32 may surround a perimeter of the second sub-reflective housing 34 to be concentric with the second sub-reflective housing 34. The first sub-reflective housing 32 and the second sub-reflective housing 34 provide a space by which the light emitted from the light source 40 is reflected, e.g., vertical sidewalls of the first sub-reflective housing 32 may be radially spaced apart from and parallel to the second sub-reflective housing 34. The reflective housing 30 may reflect light such that the light emitted from the light source 40 is emitted to a desired position, e.g., the substrate W, the susceptor 20, and the preheat ring 24. The reflective housing 30 may focus the light emitted from the light source 40 on the substrate W. An inner surface of the reflective housing 30 may be coated with a highly reflective material.

The light source 40 may be in the reflective housing 30, e.g., the light source 40 may be coupled to the vertical sidewall of the first sub-reflective housing 32. A plurality of light sources 40 may be provided. When a plurality of light sources 40 are provided, the plurality of light sources 40 may be arranged in a circumferential direction of the reflective housing 30. For example, the light source 40 may include a halogen lamp. The substrate W may be heated by the light emitted from the light source 40 toward the substrate W. The light emitted from the light source 40 may be absorbed by the substrate W, the susceptor 20, and the preheat ring 24 to be converted into thermal energy. The light emitted from the light source 40 may include visible light or infrared light. Specifically, the light source 40 may emit light having a wavelength in a range of about 380 nm to about 1000 nm. The light emitted from the light source 40 may pass directly through the light adjuster 90 to be introduced to the internal space 11. In addition, the light emitted from the light source 40 may be reflected by the reflective housing 30, pass through the light adjuster 90, and then be introduced into the internal space 11.

The temperature measurer 50 may be disposed toward an upper portion of the substrate W, e.g., the temperature measurer 50 may extend through the second sub-reflective housing 34 and be directed toward a center of the light adjuster 90. The temperature measurer 50 may be disposed to correspond to, e.g., extend in parallel to, a central axis A of the substrate W. The temperature measurer 50 may measure a temperature of a heating region of the substrate W. For example, the temperature measurer 50 may include a non-contact temperature sensor. For example, the temperature measurer 50 may include a pyrometer. According to an embodiment, a plurality of temperature measurers 50 may be provided.

For example, the substrate processing apparatus 1 may additionally include the lower reflective housing 70 and the lower light source 80. The lower reflective housing 70 may include a first lower reflective housing 72 and a second lower reflective housing 74. The lower light source 80 may be in the first lower reflective housing 72. The lower light source 80 may be provided in the second lower reflective housing 74. The lower reflective housing 70 may include the same material as the reflective housing 30 and may have substantially the same or similar functions. The lower light source 80 may have substantially the same or similar shape and function as the light source 40. The lower reflective housing 70 and the lower light source 80 may also be omitted.

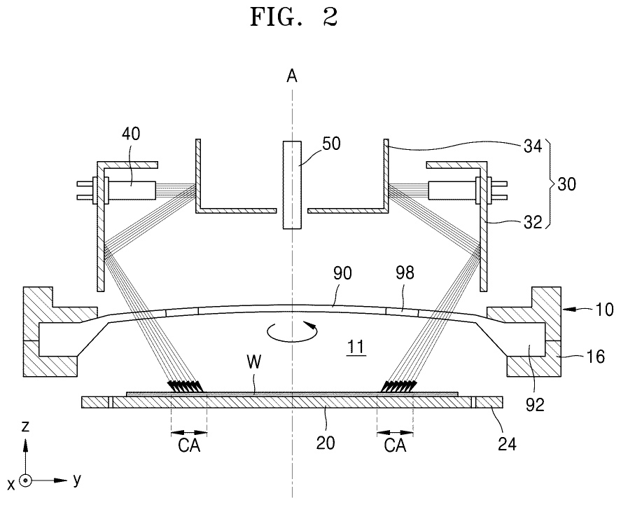

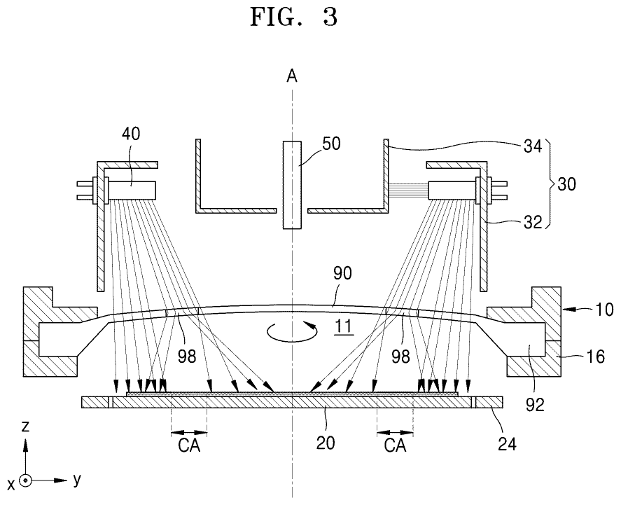

FIGS. 2 and 3 are cross-sectional views schematically illustrating states in which the light source 40 of FIG. 1 emits light onto the substrate W.

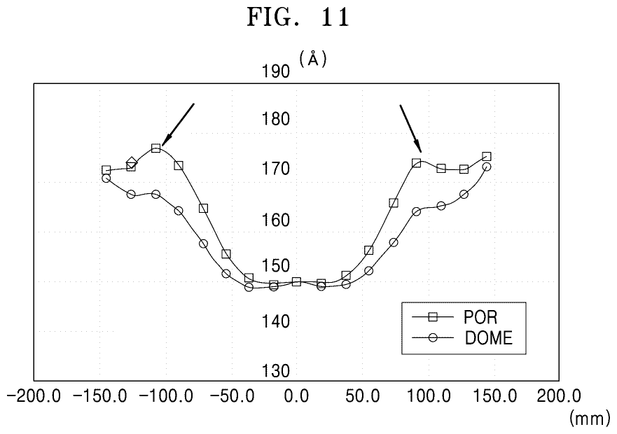

Referring to FIGS. 2 and 3, it can be seen that the amount of light emitted onto the substrate W has a dispersion difference for each region of the substrate W. That is, a uniform amount of light is not emitted to the entire region of the substrate W, and the amount of light may vary depending on regions of the substrate W. For example, when a thin film deposition process is performed on the substrate W having a size of 300 mm, the amount of light may be further increased in a region having a radius of about 100 mm, i.e., in a control region CA (see POR of FIG. 11). Therefore, in order to deposit a uniform thin film on the substrate W, a thickness of the thin film of the control region CA needs to be controlled.

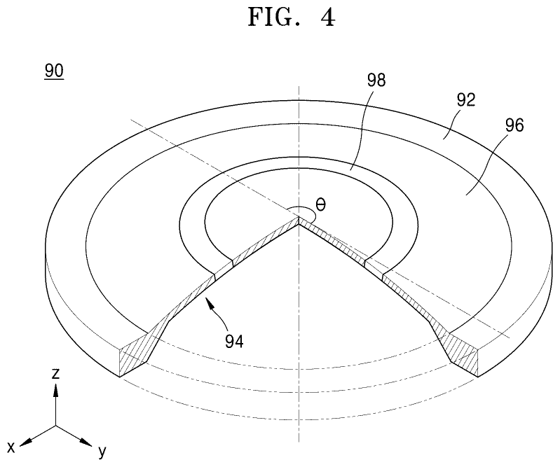

As illustrated in FIG. 2, a part of the light emitted from the light source 40 may be directed toward the second sub-reflective housing 34. The second sub-reflective housing 34 may be coated with a highly reflective material, and thus, a part of the light may be reflected by the second sub-reflective housing 34 to be directed toward the first sub-reflective housing 32. The first sub-reflective housing 32 may also be coated with a highly reflective material, and thus, a part of the light may be reflected by the first sub-reflective housing 32 to be directed toward the light adjuster 90. Specifically, a part of the light may be directed toward a lens (see 94 of FIG. 4) included in the light adjuster 90.

According to an embodiment, the lens (see 94 of FIG. 4) may be formed on a surface of the light adjuster 90 exposed to the outside of the chamber 10 (see 94 of FIG. 4) and include a transmission portion 96 (FIG. 4) and a scattering pattern portion 98. The transmission portion of the lens is configured to transmit light therethrough, and the scattering pattern portion 98 of the lens is configured to scatter light. Accordingly, in the light reflected by the first sub-reflective housing 32 and the second sub-reflective housing 34 toward the light adjuster 90, a part of the light directed toward the transmission portion may be directed toward (e.g., and incident on) the control region CA of the substrate W.

As can be seen in FIG. 3, a part of the light emitted from the light source 40 may be directed directly toward the light adjuster 90 without being reflected by the reflective housing 30. The part of the light directed directly toward the light adjuster 90 may be directed toward the transmission portion 96 and/or the scattering pattern portion 98 included in the lens (FIG. 4). As illustrated in FIG. 2, the part of the light directed toward the transmission portion may be transmitted through the transmission portion of the lens toward the control region CA of the substrate W. As illustrated in FIG. 3, the part of the light directed toward the scattering pattern portion 98 may be scattered, so as not to be directed toward the control region CA of the substrate W. Accordingly, the amount of light emitted to the control region CA of the substrate W may be adjusted by patterning the scattering pattern portion 98 in the lens 94.

The scattering pattern portion 98 may scatter at least a part of the light emission path to adjust a light emission region on the substrate W. Because the scattering pattern portion 98 scatters at least a part of the light emission path, deviation of the light emission amount for each position of the substrate W may be reduced. Accordingly, light energy is shielded, and thus, the amount of silicon growth in the control region CA may be controlled. Although not illustrated in the drawings for the sake of convenience of description, at least a part of the light toward the scattering pattern portion 98 may be emitted to the control region CA.

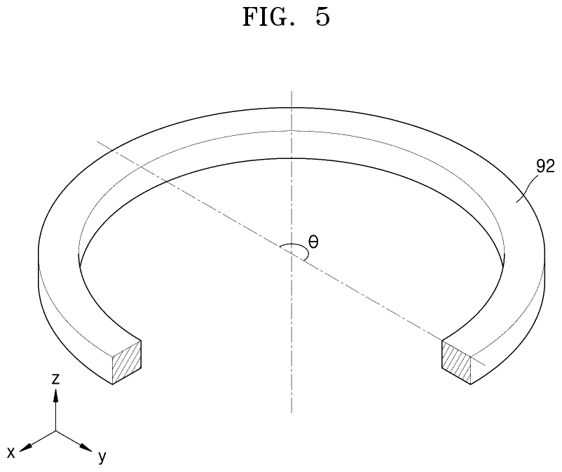

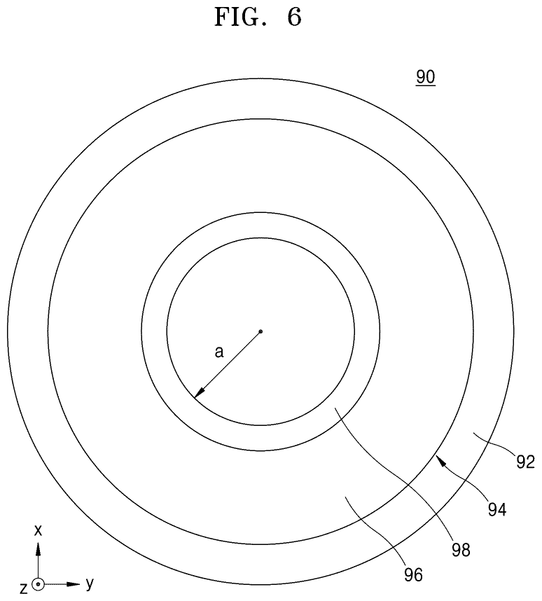

FIG. 4 is a perspective view of an embodiment of the light adjuster 90 illustrated in FIG. 1. FIG. 5 is a perspective view of a support portion 92 illustrated in FIG. 4. FIG. 6 is a plan view of the light adjuster 90 illustrated in FIG. 4.

Referring to FIGS. 1 and 4 to 6, the light adjuster 90 may include the support portion 92 supported inside the chamber 10 and the lens 94 coupled to the support portion 92. The lens 94 may be formed on the exposed surface of the support portion 92 and include a transmission portion 96 through which the light emitted from the light source 40 transmits and a scattering pattern portion 98 configured to scatter the light. As illustrated in FIG. 1, the lens 94 of the light adjuster 90 may be vertically aligned with the center of the susceptor 20, e.g., with the center of the substrate W, and have a dome shape protruding in a direction opposite to the susceptor 20, e.g., opposite to the substrate W.

The scattering pattern portion 98 may have various design parameters and have various designs. For example, as illustrated in FIGS. 5 and 6, the design parameters of the scattering pattern portion 98 may include a central angle θ and an inner radius a. The central angle θ has an apex at a center of the lens 94, e.g., which is the same as a center of the light adjuster 90 and is aligned with the center of the wafer W. The inner radius a refers to a distance from the center of the lens 94 to the inner circumference of the scattering pattern portion 98. The inner radius a of the scattering pattern portion 98 may include a parameter adjusted to deposit a uniform thin film on the substrate W. For example, as illustrated in FIG. 6, the scattering pattern portion 98 may have a complete ring shape having a central angle θ of 360 degrees, but the scattering pattern portion 98 may have an arc shape having a central angle θ less than 360 degrees.

According to an embodiment, the support portion 92 may have a parameter of the central angle θ of the lens 94, e.g., the support portion 92 may have the same central angle θ as the scattering pattern portion 98 of the lens 94. For example, as illustrated in FIG. 6, the support portion 92 may have a complete ring shape to be coupled to the lens 94. In another example, both the support portion 92 and the lens 94 may have an arc shape. Since the support portion 92 is coupled to the lens 94, various shapes may be presented.

According to an embodiment, as illustrate in FIG. 5, the support portion 92 may have a ring shape having a hole in the center. As illustrated in FIG. 6, the lens 94 may be coupled to the hole of the support portion 92, e.g., the support portion 92 may completely surround a perimeter of the lens 94. For example, the support portion 92 may be in direct contact with an entire outer perimeter of the lens 94, e.g., the lens 94 may fill the hole of the support portion 92. As further illustrated in FIG. 6, the scattering pattern portion 98 may have a ring shape, e.g., the scattering pattern portion 98 and the support portion 92 may be concentric rings. The support portion 92 may be fixed to the chamber 10.

Referring to FIG. 6, the transmission portion 96 may be defined as a region except the scattering pattern portion 98 in a surface of the lens 94. That is, as illustrated in FIG. 6, the transmission portion 96 is a region on the surface of the lens 94 other than the scattering pattern portion 98. An area of the transmission portion 96 may be greater than an area of the scattering pattern portion 98. When the light emitted from the light source 40 is directed toward the transmission portion 96, the transmission portion 96 may be configured such that the amount of transmitted light is greater than the amount of reflected light. For example, the transmission portion 96 may be made of silicon dioxide (SiO₂), quartz, sapphire, or a combination thereof.

According to an embodiment, an arithmetic mean roughness (Ra) of a surface of the scattering pattern portion 98 may be about 0.5 to about 2. In order to form the arithmetic mean roughness, the scattering pattern portion 98 may be formed by etching a partial region of the lens 94 and then annealing at a high temperature that is higher than 1100 degrees. The arithmetic mean roughness may indicate a size of irregular unevenness having a short period and relatively small amplitude on the processed metal surface. As the arithmetic mean roughness (Ra) of the scattering pattern portion 98 increases, a degree of scattering of the light emitted toward the scattering pattern portion 98 may increase.

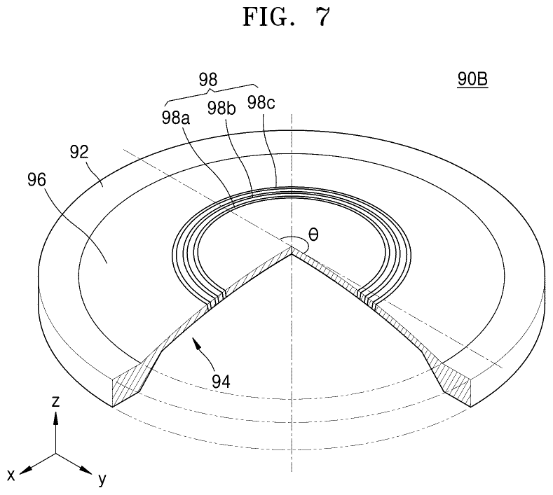

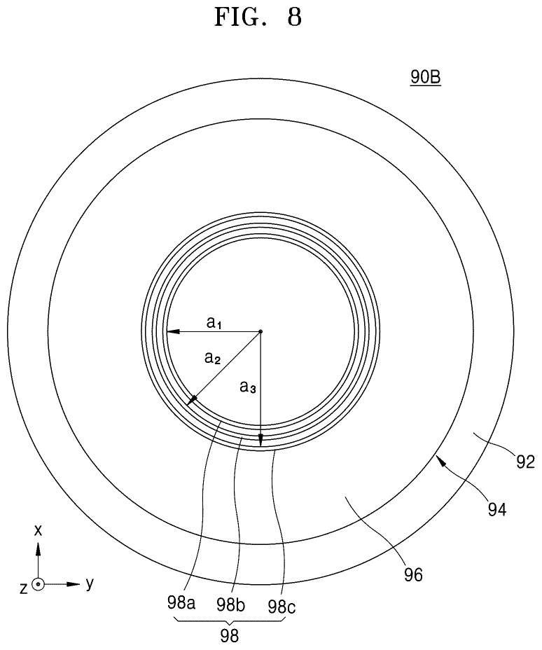

FIG. 7 is a perspective view of a light adjuster 90B according to another embodiment. FIG. 8 is a plan view of the light adjuster 90B illustrated in FIG. 7.

The light adjuster 90B I FIGS. 7-8 is the same as the light adjuster 90 of FIGS. 4-6, except that it includes a scattering pattern portion with a plurality of patterns 98a, 98b, and 98c. Same reference numerals as in FIGS. 4 to 6 denote the same members. In FIGS. 7 and 8, same descriptions given with reference to FIGS. 4 to 6 are briefly given or omitted.

Referring to FIGS. 7 and 8, the light adjuster 90B may include the support portion 92 supported inside the chamber and the lens 94 coupled to the support portion 92. The lens 94 may include the transmission portion 96 that is formed on the exposed surface of the lens 94 to transmit the light emitted from the light source 40 therethrough, and a scattering pattern portion 98 configured to scatter the light. The lens 94 may be vertically aligned at the center of the substrate W and have a dome shape protruding in a direction opposite to, e.g., oriented away from, the direction of the substrate W.

The scattering pattern portion 98 may have various design parameters and various designs. As illustrated in FIGS. 7-8, a plurality of patterns 98a, 98b, and 98c included in the scattering pattern portion 98 may have parameters, e.g., a central angle θ, and a plurality of inner radii a1, a2, and a3. The parameters of the scattering pattern portion 98, i.e., the central angle θ and the plurality of inner radii a1, a2, and a3, are not limited to specific examples and may be provided in various ways. In this case, the plurality of inner radii a1, a2, and a3 of the scattering pattern portion 98 may include parameters adjusted to deposit a uniform thin film on the substrate W. In the drawings, the scattering pattern portion 98 has a complete ring shape with a central angle θ of 360 degrees, but according to an embodiment, the scattering pattern portion 98 may have an arc shape with a central angle θ less than 360 degrees.

According to an embodiment, the support portion 92 may have a ring shape having a hole in the center, the lens 94 may be coupled to the hole, and the scattering pattern portion 98 may have a ring shape.

According to an embodiment, the scattering pattern portion 98 may include a first pattern 98a having a ring shape and a first inner radius a1, a second pattern 98b having a ring shape and a second inner radius a2, and a third pattern 98c having a ring shape and a third inner radius a3. In this case, the second pattern 98b may be located outside the first pattern 98a on the exposed surface of the lens 94, and the third pattern 98c may be located outside the second pattern 98b on the exposed surface of the lens 94.

According to an embodiment, the first inner radius a1 of the first pattern 98a is less than the second inner radius a2 of the second pattern, and the second inner radius a2 of the second pattern 98b may be less than the third inner radius a3 of the third pattern 98c. In addition, an outer radius of the first pattern 98a may be less than the second inner radius a2 of the second pattern 98b, and an outer radius of the second pattern 98b may be less than the third inner radius a3 of the third pattern 98c.

According to an embodiment, the arithmetic mean roughness (Ra) of surfaces of the first pattern 98a, the second pattern 98b, and the third pattern 98c may be about 0.5 to about 2. In this case, the arithmetic mean roughness of the first pattern 98a may be greater than the arithmetic mean roughness of the second pattern 98b, and the arithmetic mean roughness of the second pattern 98b may be greater than the arithmetic mean roughness of the third pattern 98c. However, embodiments are not limited thereto, and the arithmetic mean roughness of the first pattern 98a may be less than the arithmetic mean roughness of the second pattern 98b, and the arithmetic mean roughness of the second pattern 98b may be less than the arithmetic mean roughness of the third pattern 98c. The degrees of scattering of the light passing through the scattering pattern portion 98 may be different from each other according to wavelengths of the light emitted from the light source 40. Accordingly, a magnitude relationship between the arithmetic mean roughness of the first pattern 98a, the second pattern 98b, and the third pattern 98c may vary depending on the light emitted from the light source 40. The amount of light emitted to the control region (CA of FIG. 2) of the substrate W may be adjusted by appropriately changing the arithmetic mean roughness of the first pattern 98a, the second pattern 98b, and the third pattern 98c.

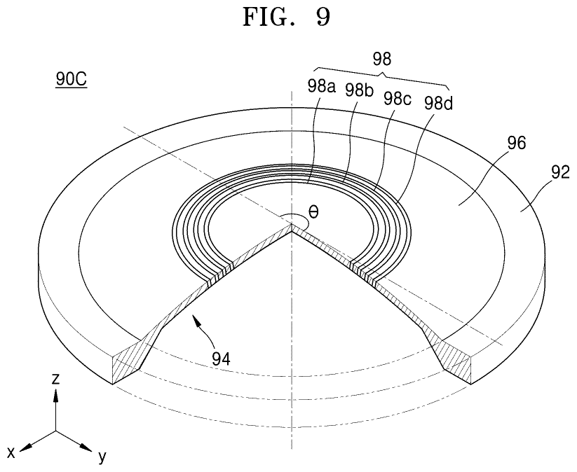

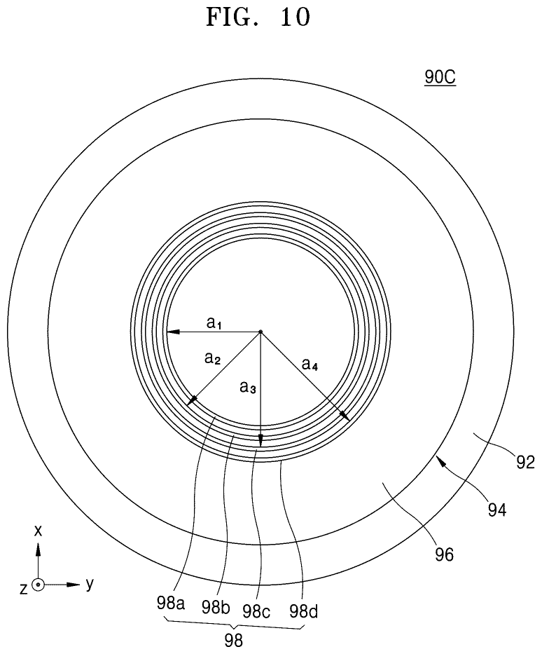

FIG. 9 is a perspective view of a light adjuster 90C according to another embodiment. FIG. 10 is a plan view of the light adjuster 90C illustrated in FIG. 9.

The light adjuster 90C is the same as the light adjuster 90 of FIGS. 4 to 6, except that a scattering pattern portion 98 includes a plurality of patterns 98a, 98b, 98c, and 98d. The same reference numerals as in FIGS. 4 to 6 denote the same members. In FIGS. 9 and 10, same descriptions given with reference to FIGS. 4 to 6 are briefly given or omitted.

Referring to FIGS. 9 and 10, the light adjuster 90C may include the support portion 92 supported inside the chamber and the lens 94 coupled to the support portion 92. The lens 94 may include the transmission portion 96 that is formed on the exposed surface of the lens 94 to transmit the light emitted from the light source 40 therethrough, and a scattering pattern portion 98 configured to scatter the light. The lens 94 may be vertically aligned at the center of the substrate and have a dome shape protruding in a direction opposite to the direction toward the substrate.

The scattering pattern portion 98 may have various design parameters and various designs. According to an embodiment, a plurality of patterns 98a, 98b, 98c, and 98d included in the scattering pattern portion 98 may have parameters, e.g., a central angle θ, and a plurality of inner radii a1, a2, a3, and a4. The parameters of the scattering pattern portion 98, i.e., the central angle θ and the plurality of inner radii a1, a2, a3, and a4, are not limited to specific examples and may be provided in various ways. In this case, the plurality of inner radii a1, a2, a3, and a4 of the scattering pattern portion 98 may include parameters adjusted to deposit a uniform thin film on the substrate W. In the drawings, the scattering pattern portion 98 has a complete ring shape with a central angle θ of 360 degrees, but according to an embodiment, the scattering pattern portion 98 may have an arc shape with a central angle θ less than 360 degrees.

According to an embodiment, the support portion 92 may have a ring shape having a hole in the center, the lens 94 may be coupled to the hole, and the scattering pattern portion 98 may have a ring shape.

According to an embodiment, the scattering pattern portion 98 may include a first pattern 98a having a ring shape and a first inner radius, a second pattern 98b having a ring shape and a second inner radius, a third pattern 98c having a ring shape and a third inner radius, and a fourth pattern 98d having a ring shape and a fourth inner radius. In this case, the second pattern 98b may be located outside the first pattern 98a on the exposed surface of the lens 94, the third pattern 98c may be located outside the second pattern 98b on the exposed surface of the lens 94, and the fourth pattern 98d may be located outside the third pattern 98c on the exposed surface of the lens 94.

According to an embodiment, the first inner radius a1 of the first pattern 98a is less than the second inner radius a2 of the second pattern, the second inner radius a2 of the second pattern 98b is less than the third inner radius a3 of the third pattern 98c, and the third inner radius a3 of the third pattern 98c is less than the fourth inner radius a4 of the fourth pattern 98d. In addition, an outer radius of the first pattern 98a may be less than the second inner radius a2 of the second pattern 98b, an outer radius of the second pattern 98b may be less than the third inner radius a3 of the third pattern 98c, and an outer radius of the third pattern 98c may be less than the fourth inner radius a3 of the fourth pattern 98d.

According to an embodiment, the arithmetic mean roughness (Ra) of surfaces of the first pattern 98a, the second pattern 98b, the third pattern 98c, and the fourth pattern 98d may be about 0.5 to about 2. In this case, the arithmetic mean roughness of the first pattern 98a may be greater than the arithmetic mean roughness of the second pattern 98b, the arithmetic mean roughness of the second pattern 98b may be greater than the arithmetic mean roughness of the third pattern 98c, and the arithmetic mean roughness of the third pattern 98c may be greater than the arithmetic mean roughness of the fourth pattern 98d. However, embodiments are not limited thereto, and the arithmetic mean roughness of the first pattern 98a may be less than the arithmetic mean roughness of the second pattern 98b, the arithmetic mean roughness of the second pattern 98b may be less than the arithmetic mean roughness of the third pattern 98c, and the arithmetic mean roughness of the third pattern 98c may be less than the arithmetic mean roughness of the fourth pattern 98d. The degrees of scattering of the light passing through the scattering pattern portion 98 may be different from each other according to wavelengths of the light emitted from the light source 40 of FIG. 1. Accordingly, a magnitude relationship between the arithmetic mean roughness of the first pattern 98a, the second pattern 98b, the third pattern 98c, and the fourth pattern 98d may vary depending on the light emitted from the light source 40 of FIG. 1. The amount of light emitted to the control region (CA of FIG. 2) of the substrate W may be adjusted by appropriately changing the arithmetic mean roughness of the first pattern 98a, the second pattern 98b, the third pattern 98c, and the fourth pattern 98d.

FIG. 11 is a graph of experimental data illustrating thin film distribution when the light adjuster 90C illustrated in FIG. 9 is used.

Referring to FIG. 11, the horizontal axis of the graph denotes a distance of the scattering pattern portion 98 from the center of substrate (e.g., in nm) with the center set to 0. The vertical axis of the graph denotes a thin film thickness distribution on the substrate. A line DOME indicated by circle dots denotes the thin film distribution when the light adjuster 90C is used, and a line POR indicated by square dots denotes the thin film distribution when the light adjuster 90C is not used. FIG. 11 illustrates the thin film distribution according to a position of the substrate W. In this case, values of the thin film distribution may be arbitrary values.

Referring to FIG. 11, it can be seen that, when the light adjuster 90C is used, the distribution is reduced in a region of about 100 mm, i.e., in the control region CA. As parameters, e.g., the first inner radius a1 of the first pattern, the second inner radius a2 of the second pattern, the third inner radius a3 of the third pattern, and the fourth inner radius a4 of the fourth pattern, the central angle θ, and so on change, a roughness reduction value may change. That is, by correcting the illuminance of light being introduced into the internal space 11 in which the thin film deposition process is performed in the chamber 10, a temperature of the substrate W may be uniformly controlled, and thus, a uniform single crystal film may be grown over the entire region of the substrate W.

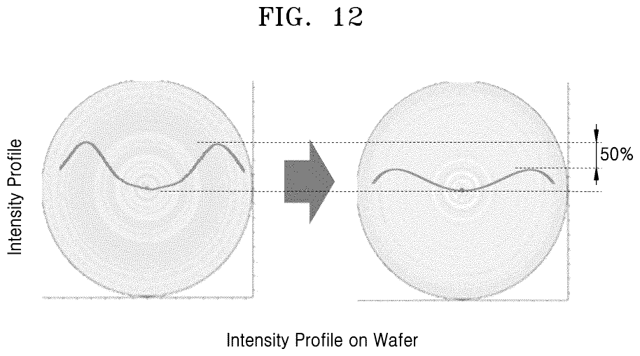

FIG. 12 is experimental data illustrating the intensity of light according to a region of the substrate W when the light adjuster 90C illustrated in FIG. 9 is used.

Referring to FIG. 12, a graph illustrated on the left in FIG. 12 shows experimental data indicating the intensity of light depending on regions of the substrate W when the light adjuster 90C is not used, and a graph illustrated on the right in FIG. 12 shows experimental data indicating the intensity of light depending on regions of the substrate W when the light adjuster 90C is used. As illustrated in FIG. 12, it can be seen that, when the light adjuster 90C is used, the intensity of light in the control region CA of FIG. 2 is reduced by about 50%.

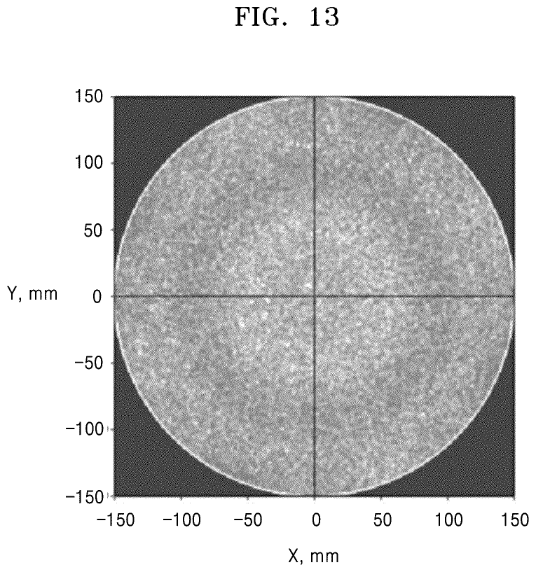

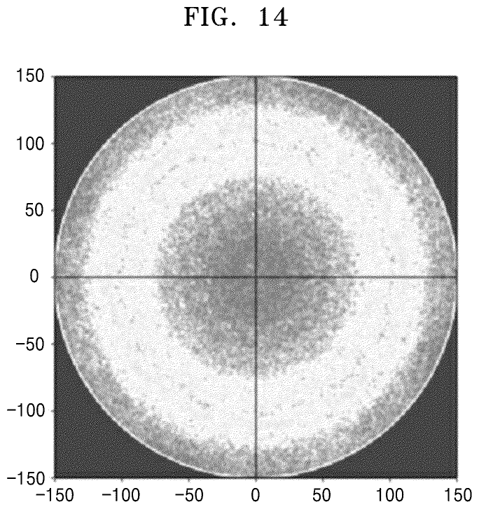

FIG. 13 is experimental data illustrating a temperature distribution depending on regions of the substrate W when the light adjuster 90C is not used. FIG. 14 is experimental data illustrating a temperature distribution depending on regions of the substrate W when the light adjuster 90C illustrated in FIG. 9 is used. In detail, FIGS. 13 and 14 are experimental data illustrating a temperature distribution depending on a region of the substrate W, when the light emitted from the light source 40 of FIG. 1 is not directed toward the reflective housing 30 of FIG. 1 but is directed directly toward the substrate W of FIG. 1.

Referring to FIG. 13, it can be seen that, when the light emitted from the light source is not directed toward the reflective housing 30 of FIG. 1 but is directed directly toward the substrate, a temperature of a region within 100 mm of the substrate, i.e., a temperature of the control region CA of FIG. 2, is higher than temperatures in other regions.

However, referring to FIG. 14, it can be seen that, when the light adjuster 90C illustrated in FIG. 9 is used, the light emitted from the light source is not directed toward the reflective housing 30 of FIG. 1 but is directed directly toward the substrate, the temperature of the region within 100 mm of the substrate, i.e., the temperature of the control region CA of FIG. 2, is lower than temperatures in other regions. That is, a light shielding ability of the scattering pattern portion 98 included in the light adjuster 90C of FIG. 9 may be checked through the experimental data of FIGS. 13 and 14.

By way of summation and review, embodiments provide a substrate processing apparatus that may form a thin film having a uniform thickness. Embodiments also provide a substrate processing apparatus that may heat a substrate to a uniform temperature.

That is, according to embodiments, a substrate processing apparatus includes a structure having a specific transmittance between a light source and a substrate. The structure includes a transmission portion and a light scattering pattern portion with a predetermined surface roughness value, so light having a specific wavelength may be scattered by adjusting an area ratio of the light scattering pattern portion and the transmission portion.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate processing apparatus, comprising:
a chamber including a susceptor to support a substrate;
a reflective housing outside the chamber;
a light source in the reflective housing, the light source being configured to emit a light toward the susceptor; and
a light adjuster between the light source and the susceptor, the light adjuster including a support portion supported inside the chamber and a lens coupled to the support portion, and the lens including a transmission portion configured to transmit the light and a scattering pattern portion configured to scatter the light.

2. The substrate processing apparatus as claimed in claim 1, wherein the light source emits light having a wavelength in a range of about 380 nm to about 1000 nm.

3. The substrate processing apparatus as claimed in claim 1, wherein the transmission portion includes one of SiO₂, sapphire, and a combination thereof.

4. The substrate processing apparatus as claimed in claim 1, further comprising an internal space in the chamber, the internal space being between the light adjuster and the susceptor, and the internal space being maintained at a vacuum state.

5. The substrate processing apparatus as claimed in claim 1, wherein the scattering pattern portion of the lens includes a surface with an arithmetic mean roughness of about 0.5 to about 2.

6. The substrate processing apparatus as claimed in claim 1, wherein the lens is aligned in a direction perpendicular to a center of the susceptor, the lens having a dome shape protruding in a direction opposite to the susceptor.

7. The substrate processing apparatus as claimed in claim 1, wherein an area of the transmission portion is greater than an area of the scattering pattern portion.

8. The substrate processing apparatus as claimed in claim 1, wherein the reflective housing reflects at least a part of the light.

9. The substrate processing apparatus as claimed in claim 1, wherein the support portion is fixed to the chamber, and the scattering pattern portion has a ring shape.

10. A substrate processing apparatus, comprising:
a chamber including a susceptor to support a substrate;
a reflective housing outside the chamber;
a light source in the reflective housing, the light source being configured to emit a light toward the susceptor; and
a light adjuster between the light source and the susceptor, the light adjuster including:
a support portion supported inside the chamber, and
a lens coupled to the support portion, the lens including:
a transmission portion on a surface of the lens and configured to transmit the light therethrough, and
a scattering pattern portion configured to scatter the light, the scattering pattern portion including a first pattern having a ring shape and a first inner radius, a second pattern having a ring shape and a second inner radius, and a third pattern having a ring shape and a third inner radius.

11. The substrate processing apparatus as claimed in claim 10, wherein the lens is aligned in a direction perpendicular to a center of the susceptor, the lens having a dome shape protruding in a direction opposite to the susceptor.

12. The substrate processing apparatus as claimed in claim 10, wherein the second pattern is outside the first pattern on the surface of the lens, and the third pattern is outside the second pattern on the surface of the lens.

13. The substrate processing apparatus as claimed in claim 12, wherein the scattering pattern portion further includes a fourth pattern having a ring shape and a fourth inner radius, the fourth pattern being outside the third pattern on the surface of the lens, and the fourth inner radius being greater than the third inner radius.

14. The substrate processing apparatus as claimed in claim 10, wherein the first inner radius is less than the second inner radius, and the second inner radius is less than the third inner radius.

15. The substrate processing apparatus as claimed in claim 10, wherein an arithmetic mean roughness of the first pattern is greater than an arithmetic mean roughness of the second pattern.

16. The substrate processing apparatus as claimed in claim 10, wherein an arithmetic mean roughness of the second pattern is greater than an arithmetic mean roughness of the third pattern.

17. The substrate processing apparatus as claimed in claim 14, wherein an arithmetic mean roughness of the first pattern, an arithmetic mean roughness of the second pattern, and an arithmetic mean roughness of the third pattern are about 0.5 to about 2.

18. The substrate processing apparatus as claimed in claim 10, further comprising an internal space in the chamber, the internal space being between the light adjuster and the susceptor, and the internal space being maintained at a vacuum state.

19. A substrate processing apparatus, comprising:
a chamber including a susceptor to support a substrate;
a reflective housing outside the chamber;
a light source in the reflective housing, the light source being configured to emit light having a wavelength in a range of about 100 nm to about 400 nm toward the susceptor; and
a light adjuster between the light source and the susceptor, the light adjuster including:
a support portion supported inside the chamber, and
a lens coupled to the support portion and aligned in a direction perpendicular to a center of the susceptor, the lens having a dome shape protruding in a direction opposite to the susceptor, and the lens including:
a transmission portion on a surface of the lens and configured to transmit the light, and
a scattering pattern portion configured to scatter the light, the scattering pattern portion includes on the surface of the lens a first pattern having a ring shape and a first inner radius, a second pattern having a ring shape and a second inner radius greater than the first inner radius, and a third pattern having a ring shape and a third inner radius greater than the second inner radius,
wherein the second pattern is outside the first pattern on the surface of the lens, and the third pattern is outside the second pattern on the surface of the lens, and
wherein an arithmetic mean roughness of the first pattern is greater than an arithmetic mean roughness of the second pattern, the arithmetic mean roughness of the second pattern is greater than an arithmetic mean roughness of the third pattern, and the arithmetic mean roughness of the first pattern, the arithmetic mean roughness of the second pattern, and the arithmetic mean roughness of the third pattern are about 0.5 to about 2.

20. The substrate processing apparatus as claimed in claim 19, wherein the scattering pattern portion further includes a fourth pattern having a ring shape and a fourth inner radius, the fourth pattern being outside the third pattern on the exposed surface of the lens, and the fourth inner radius being greater than the third inner radius.
